(19) United States
(12) Patent Application Publication
(10) Pub. No.: US 2013/0112134 A1
(43) Pub. Date: May 9, 2013

(54) Method and Systems for Characterization and Production of High Quality Silicon

(71) Applicants: David C. Spencer, Heath, TX (US); Jimmie D. Walter, Anna, TX (US); Friedrich H. Doerbeck, Dallas, TX (US)

(72) Inventors: David C. Spencer, Heath, TX (US); Jimmie D. Walter, Anna, TX (US); Friedrich H. Doerbeck, Dallas, TX (US)

(73) Assignee: GIGA INDUSTRIES, INC., Garland, TX (US)

(21) Appl. No.: 13/601,847

(22) Filed: Aug. 31, 2012

Related U.S. Application Data
(63) Continuation-in-part of application No. 12/589,534, filed on Feb. 23, 2009, now abandoned.

(51) Int. Cl. C30B 15/20; C30B 15/08; C30B 15/14

(52) U.S. Cl. CPC C30B 15/20; C30B 15/14; C30B 15/08
USPC 117/13; 117/216

(57) ABSTRACT

Computer controlled quality control methods for manufacturing high purity polycrystalline granules are introduced. Polycrystalline silicon granules are sampled and converted into single crystal specimen in computer controlled system, eliminating the need of human operator in controlling the processing parameters. Single crystal silicon test samples, then characterized by FTIR and other standard analysis, are therefore more representative of the starting granular silicon.

### CROSS-REFERENCE TO RELATED APPLICATIONS:

The present application claims the benefit of the filing date of pending U.S. patent application Ser. No. 12/589,534, filed Feb. 23, 2009, titled “Method and Systems for Characterization and Production of High Quality Silicon;” U.S. Provisional Application No. 61/154,630, filed Feb. 23, 2009; and U.S. Provisional Application No. 61/154,927, filed Feb. 24, 2009, the disclosures of which are hereby incorporated by reference herein in their entirety.

### TECHNICAL FIELD

This Application is directed, in general, to a process of silicon manufacturing and, more specifically, to a silicon micro-puller used for a conversion of polycrystaline silicon granules to monocrystaline silicon samples, as necessary for optical analysis.

### BACKGROUND

Ultra-pure polysilicon is used in the semiconductor industry as the starting material for the growth of single crystals, from which then wafers are produced by grinding, slicing, lapping and polishing steps. Conductive polysilicon also finds applications as gate material for MOSFET and CMOS structures.

Before the large scale growth of single crystal Silicon ingots, the concentration levels of contaminants and dopants (such as Carbon, Boron, Phosphorus, Arsenic) in the polycrystalline starting material has to be known. Then the controlled addition of dopants to the silicon melt can be achieved.

Current standard practices for production control, quality assurance and material research is by Float-Zone Crystal Growth and Melter-Zoner Spectroscopies. See ASTM documents F 1708-96 “Standard Practice for Evaluation of Granular Polysilicon by Melter-Zoner Spectroscopies;” F 1723-96 “Standard Practice for Evaluation of Polycrystalline Silicon Rods by Float-Zone Crystal Growth and Spectroscopy;” F 1630-95 “Standard Test Method for Low Temperature FT-IR Analysis of Single Crystal Silicon for III-V impurities;” F 1389-92 “Standard Test Methods for Photoluminescence Analysis of Single Crystal Silicon for III-V impurities;” F 1391-93 “Standard Test Method for Substitutional Atomic Carbon Content of Silicon by Infrared Absorption.” The cited documents are contained e.g. in the 1998 Annual Book of ASTM Standards, Volume 10.05 Electronics (II). These documents are hereby incorporated by reference in their entirety.

The Document F 1723-96 “Standard Practice for Evaluation of Polycrystalline Silicon Rods by Float-Zone Crystal Growth and Spectroscopy,” applies to the treatment and test of polycrystalline silicon rods as produced by the Siemens Process. This process does not yield polycrystalline Silicon pebbles but large polycrystalline cylinders. Small diameter cylinders have to be cut and converted to single crystal by a process which is physically identical to the conversion of polysilicon pebbles. The applied test methods are then also identical.

The current standard quality control for manufacturing granular polysilicon uses the Float-Zone Crystal Growth method which takes place in a vertical quartz tube under flowing high purity argon. The silicon is inductively heated to the melting point using a microwave generator and an RF coil surrounding the quartz tube.

Briefly, samples of granular polysilicon pebbles are placed into the quartz tube of a Melter-Float Zone Apparatus in which the granular pebbles rest on a polytetrafluoroethylene (“PTFE”) plunger-diffuser. The tube is filled with polysilicon pebbles until the top of the pebble charge comes close to the lower part of the RF coil. A silicon pedestal is mounted on the upper chuck and centered within the quartz tube. The position of the whole carriage is manually adjusted so that the silicon pedestal extends into the RF coil.

Argon gas is first blown at higher flow rate through the PTFE plunger-diffuser to replace the oxygen in the quartz tube. The flow rate is later adjusted to a value just sufficient enough that only the top layer of granules is fluidized.

A hydrogen-air torch placed outside the quartz tube is ignited to heat the silicon pedestal to a temperature sufficiently high so that the electrical conductivity is raised until the silicon couples with the radio frequency (RF) field. An RF power coil is first turned to 80% of the operating power needed for melting silicon. Once the pedestal is observed to glow the torch is manually turned off and removed, and the RF power is manually increased until the bottom of the pedestal melts.

The PTFE plunger is manually moved until the fluidized silicon pebbles at the top of the pebble column touch the liquid end of the pedestal and go into solution. As the Silicon granules melt into the pedestal and the melt volume increases, the operator starts moving the entire carriage upward. The upper boundary of the liquid Silicon moves out of the working zone of the RF coil. Silicon crystallizes and forms the consolidated polysilicon rod.

The PTFE plunger-diffuser is then removed and a single crystal silicon seed (2.5×2.5×100 mm) (typically <100> oriented) is mounted in the lower chuck and the shaft is reinstalled. The lower shaft is manually moved upward until the seed crystal is about 5 mm below the tip of the consolidated polysilicon rod previously produced. The entire tube is purged with argon gas

The hydrogen torch is manually ignited while the RF power is set at 80% of the power needed to melt silicon. When the bottom of the consolidated polysilicon rod begins to glow indicating RF coupling, the torch is turned off and removed. The RF power is increased until the bottom of the consolidated rod is molten. The single crystal silicon seed is then manually raised to penetrate into the melt and is held in this position until thermal equilibrium is established between the tip of the seed, the melt, and the bottom of the consolidated polysilicon rod.

Typically, an optimum RF power for the one-pass zone leveling process needs to be experimentally established. Next the motorized carriage movement is initiated. Moving the carriage downward, the liquid zone is moved upward and single crystal silicon growth is occurring.

The appearance of four growth facet lines for the case of <100>-oriented seeds indicate single crystalline growth.

When a sufficiently long Silicon single crystal has been grown, the lower chuck is manually moved downward to separate the grown single crystal from the melt.

After a visual inspection of the harvested single crystal silicon one or several 2 to 4 mm thick slices are cut from specified locations and submitted to low temperature FTIR analysis and other standard analyses.

Highest purity silicon has a background contamination level down to 1×10¹² per cubic centimeter, corresponding to an electrical conductivity of approximately 1 E4 ohm cm. In order to achieve full sensitivity of the available optical tests, such as low temperature FTIR, photoluminescence etc., required for these low concentration, the single crystal quality has to be as high as possible.

The prior art manually-operated process often produces insufficient control of the growth environment and growth conditions (gas pressure, gas flow rate, temperature, growth rate i.e. movements of the seed crystal and the polycrystalline source material). Moreover, stresses and defects in the single crystal render the optical low temperature tests less sensitive.

### SUMMARY

In one preferred embodiment, small samples of polycrystalline semiconductor granules are taken from the production stream and are tested in a computer controlled quality control system wherein the granules are first consolidated into a polycrystalline rod.

In another preferred embodiment, the consolidated polycrystalline semiconductor rod is further converted into a single crystal using a computer controlled micro-pulling machine.

In another preferred embodiment, the computer controlled consolidation process and the computer controlled micro-pulling are performed in the same machine in situ.

In another preferred embodiment the computer controlled consolidation process and the computer controlled micro-pulling process are performed in two separate machines in a coordinated fashion. The resulting single crystal samples are submitted to highly sensitive tests, e.g. FTIR, IR spectroscopy and others, for determination of contamination levels.

In another preferred embodiment, previously used processing parameters are stored in the computer of the micro-pulling system for later use and analysis. A touch screen may be used to display the status of the process parameters. Parameters may be changed either by direct input commands to the touch screen or through other user interfaces, such as an Internet connection, at remote terminals. Remote terminals may also be used for process monitoring.

### BRIEF DESCRIPTION

Reference is now made to the following descriptions taken in conjunction with the accompanying drawings, in which:

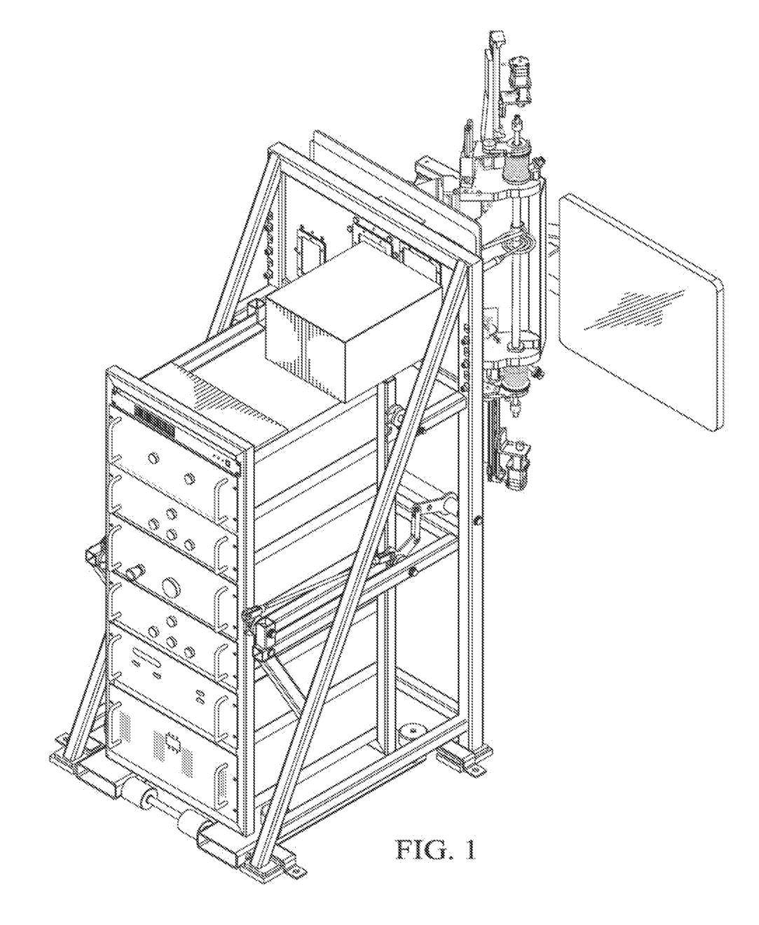

FIG. 1 presents an overview drawing of an example system in accordance with the present application.

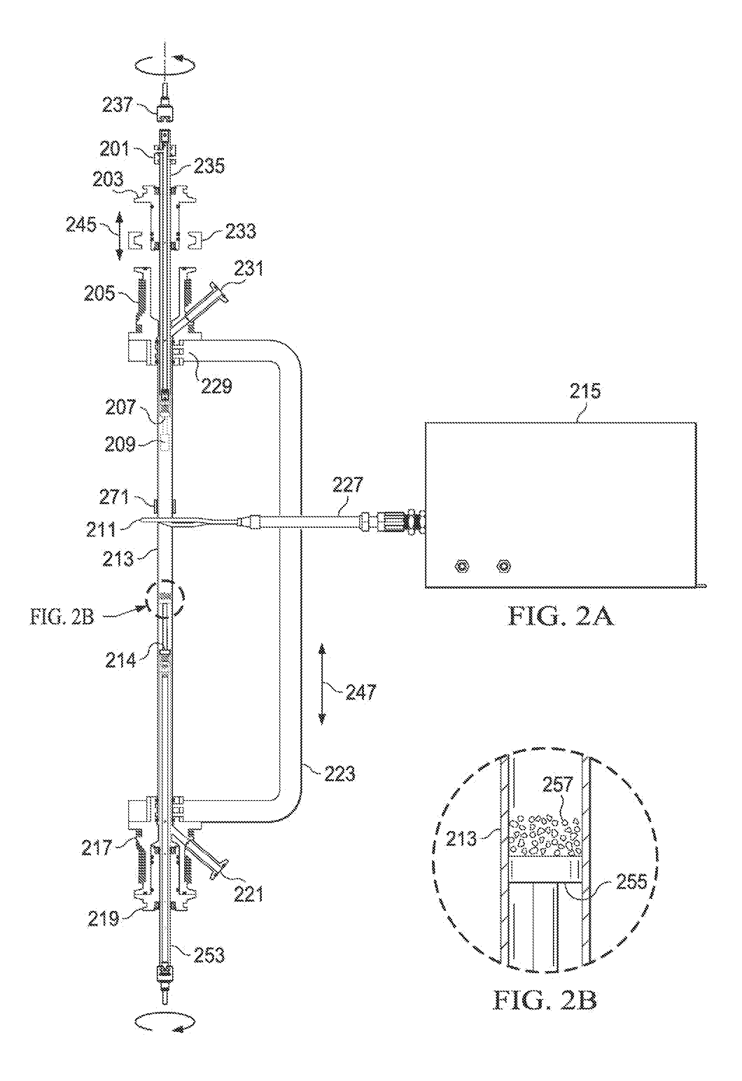

FIG. 2 shows a cross sectional drawing of the process quartz tube and attached components. The numbers refer to the List of Assigned Numbers which identifies these components by name.

FIG. 2B shows poly-silicon granules 257 supported by plunger 255, within the argon gas purged quartz tube 213.

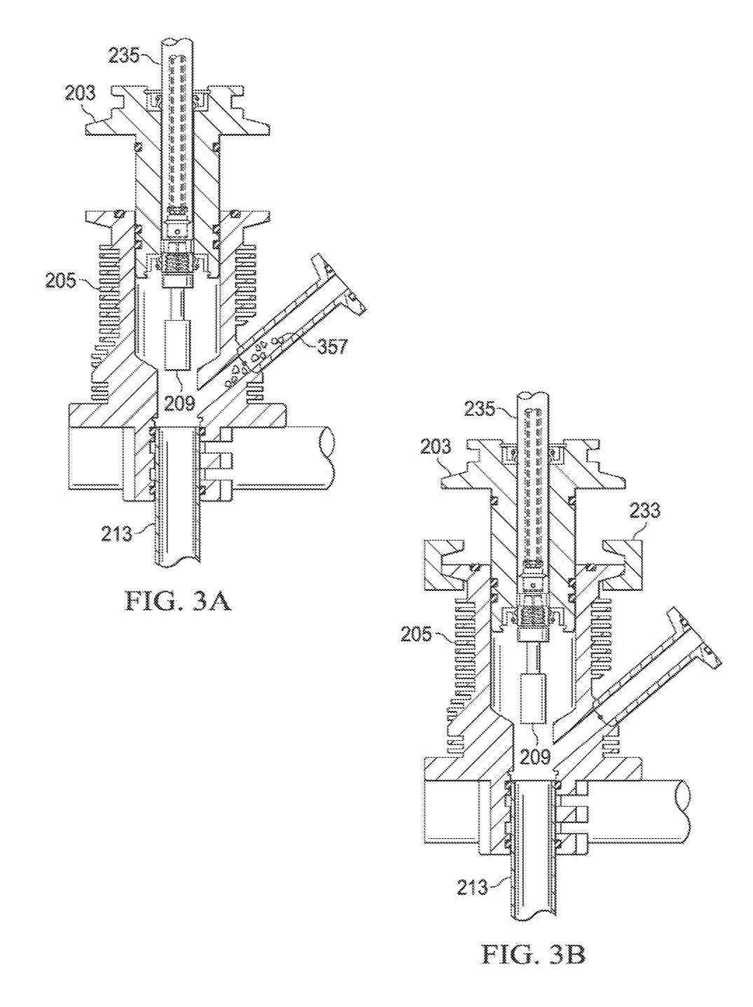

FIG. 3A shows a cross sectional view of details of the components at the upper end of the quartz process tube: the base mount, the shaft guide in elevated position, and associated seals etc. as an example system in accordance with the present application.

FIG. 3B shows a cross sectional view of the upper components, adding the clamp 233 shown in the applied position which is used when the shaft guide and the base mount are to be pressed together in accordance with the present application.

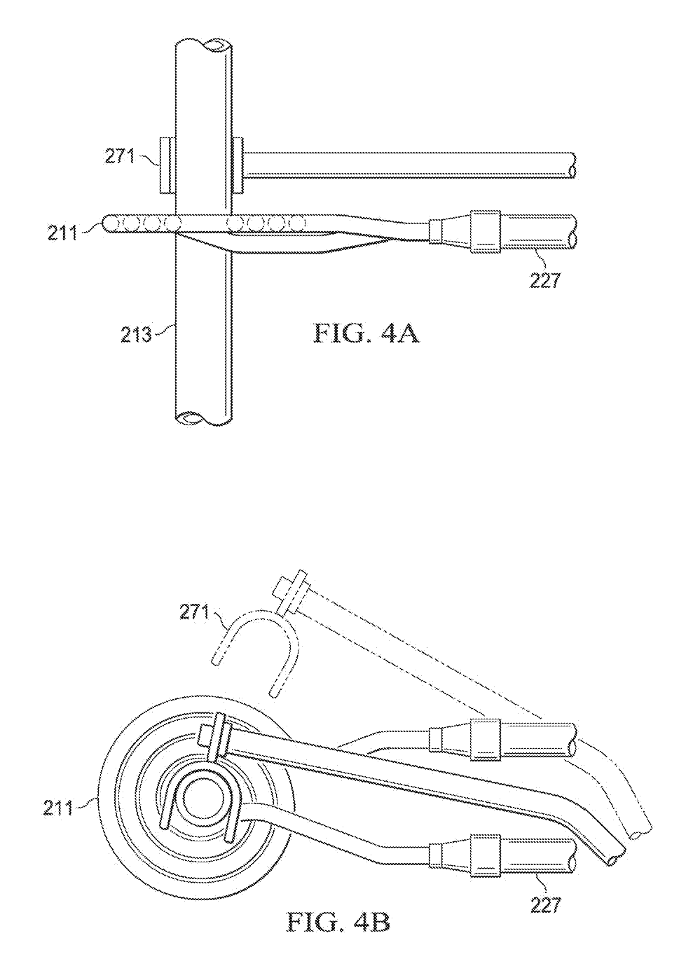

FIGS. 4A and 4B show cross-sectional side and top views of an example process tube, encircled by the RF-heating coil 211 and with the susceptor 271 in engaged and disengaged positions in accordance with the present application.

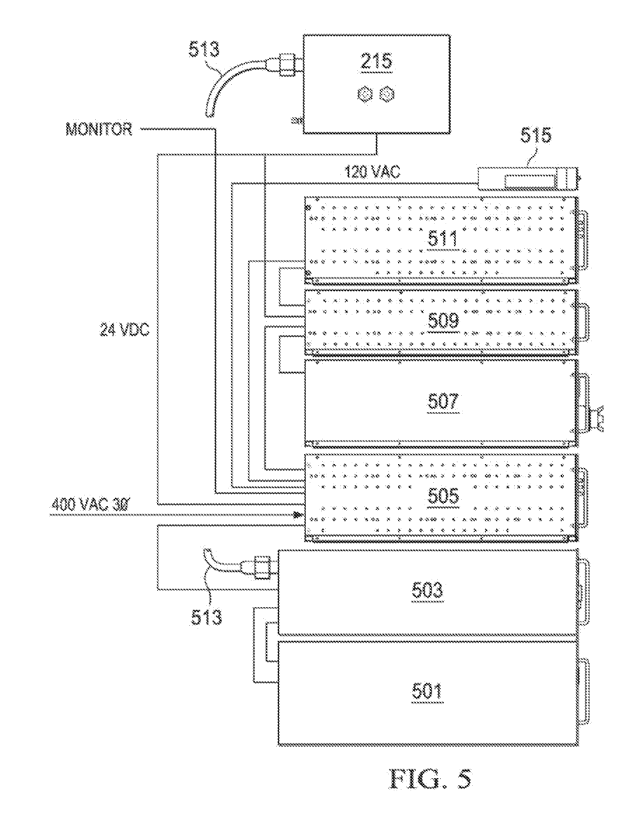

FIG. 5 shows a schematic view of an example of the organization of the various components used for the Process Control of the whole System, organized in 6 drawers, and the CPU 515 and the automated RF matching network 215, in accordance with the present application.

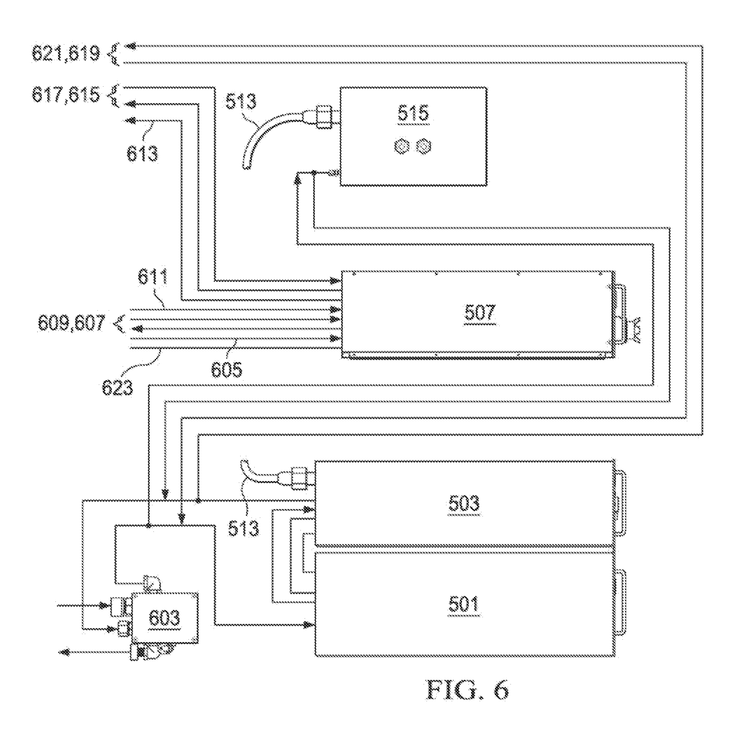

FIG. 6 shows a schematic view of an example Ambient Control, to control gas pressure, gas flow, fluid flow, with components placed in identified drawers, in accordance with the present application.

### DETAILED DESCRIPTION

Generally, the present application discloses new approaches to the quality control process for manufacturing high purity polycrystalline semiconductor granules, such as by using computer control, for a consolidation process as well as a micro-pulling process.

It is contemplated and intended that the system design applies to both single crystal growth from granular polysilicon pebbles and to single crystal growth from other polysilicon samples, for example, polysilicon samples cut from large polysilicon rods, for the process of quality control.

The disclosed innovations, in various embodiments, provide one or more of at least the following advantages. However, not all of these advantages result from every one of the innovations disclosed.
Improved precision of test results resulting in tighter process control;
Higher reproducibility;
Faster turnaround time; and
Reduced learning curve for entry level operators.

These factors can contribute to yield improvements for the process of mass production of granular silicon.

Generally, when silicon is heated it reacts with water vapor or oxygen to form a surface layer of silicon dioxide. Pure silicon is a solid with the same crystalline structure as diamond. It has a melting point of 2570° F. (1410° C.). The high melting temperature provides a challenge for consolidating and converting polysilicon into single silicon crystal. The conversion process must be performed in an oxygen and water free environment and the temperature must be precisely controlled at all time.

The presented automated process and system for converting polysilicon material into a single silicon crystal, performed at a temperature of around 1410° C. in pure argon gas, provides the controlled environment with the needed consistency and control.

Turning to drawing FIG. 1, illustrated is a view of the micro-puller system in accordance with the present application. Generally, this micro-puller system is significantly smaller than prior art micro-pullers. Furthermore, most support components for the micro-puller system can be placed outside of a clean-room. Support has been assigned to two physical frames; one holding drawers containing power supplies, process control components, the RF generator 503, and in some embodiments, containing everything other than the reaction tube 213, such as a quartz tube, and any directly connected components, e.g. the base mounts 205 and 217 with shaft guides 203 and 219 etc. The inner frame can be rolled into the outer frame. The frames are connected together in a manner such that the weight is transferred to the outer frame near the floor, which leads to a low center of gravity for the outer frame with its attached process related hardware, thus offering maximum mechanical stability and resistance to vibrations. The outer frame also has provisions for mechanical anchoring to a solid floor.

FIG. 2 presents a schematic drawing, a side view of the part of the system where the process takes place.

The presented List of Assigned Numerals defines names and functions of system and process components as used throughout the text.

### LIST OF ASSIGNED NUMERALS

201 Cooling water seal
203 Upper shaft guide
205 Upper base mount
207 Upper chuck
209 Silicon pedestal
211 RF coil
213 Quartz tube
214 Lower chuck
215 Automated RF tuning network
217 Lower base mount
219 Lower shaft guide
221 Lower gas port
223 Carriage
227 RF-power connection
229 Cooling gas port
231 Upper gas port
233 Base mount clamp
235 Upper shaft
237 Bayonet coupling
245 Axis, shaft guide up/down
247 Axis, carriage up/down
253 Lower shaft
255 Plunger
257 Poly-Silicon granules
271 Susceptor
501 RF power supply
503 RF generator
505 System power supplies
507 Fluid, vacuum, gas control unit
509 Actuator drives, power supplies
511 Controller, I/O boards
513 RF power cable
515 CPU
603 Flow control for cooling water
605 Air supply to drawer #507
619, 621 Shaft cooling water
615, 617 Argon gas to quartz tube
607, 609 Argon gas to drawer #507
611, 613 Cooling air for base mount
623 Vacuum to drawer #507

Also shown are lines for cooling water to drawers 501 and 503.

The power and control system is schematically shown in FIG. 5. Organized in six drawers, it includes an RF power supply 501, an RF generator 503, a system power supply 505, a fluid vacuum and gas control unity 507, actuator drivers with power supplies 509, a controller and I/O cards 511, a CPU 501, an automated matching RF network 215, which transmits RF power from the microwave power generator 503, through cable 513 and the RF power connection 227 to the stationary RF coil 211.

The CPU 515 accepts programs and commands either remotely from a touch screen or a remote terminal. The remote terminal can operate the system in a similar manner as a local touch screen. The remote terminal can be employed via an Internet connection to the system and can be operated by a remote operator.

After instructions are received by the CPU 515, they are converted into machine instructions. The machine instructions are communicated to the control unit 511 and to the RF power generator 503, which in turn is powered by the RF power supply 501. Inserted between the RF generator 503 and the RF coil 211 is the automated impedance matching network 215. It measures the reflected and the forward microwave power and automatically adjusts tuning components to minimize the reflected RF power.

Employment of the impedance matching network 215 leads improved RF-energy transfer, to better temperature stability and temperature control and thereby to improvements of the overall process control.

The controller unit 511 sends signals to the ambient control unit 507, which controls all gas/vacuum components (on/off valves, a mass flow controller etc.) and to the actuator unit 509, which controls various motions, such as all motions of the upper shaft 235, the lower shaft 253, and the carriage 223, all presented in FIG. 2, and to be discussed below.

In the controller system, the CPU 515 receives data from a feedback unit or from a human operator. One critical parameter is the size of the liquid silicon melt. This feedback, originating either from a device or a human, enables the system to precisely follow a pre-programmed process sequence for the consolidation of polycrystalline silicon granules into a polysilicon rod and then for its conversion into a monocrystaline test sample.

Drawer 511 (controllers and I/O boards) also contains the RF power control unit, using connections to drawer 503 (RF generator) and to the Automated RF-Tuning Network 215. Data from radiation sensors can flow to drawer 511 (controller & I/O boards). Drives receive their commands from drawer 509 (actuator drives & power supplies).

The process takes place in a vertical quartz tube 213, under flowing high purity argon.

For processing polycrystalline Silicon granules, which have a typical, but not well defined, diameter of approximately 1 to 5 mm, the first step consists of a conversion into a polycrystalline silicon rod grown by this process onto a silicon pedestal 209.

For the consolidation of the silicon pebbles, a silicon rod, called pedestal 209, is used as base.

Extending from the upper shaft 235 the pedestal 209 is clamped into the chuck 207. Both shafts 235 and 253 can be raised, lowered and rotated, thereby moving the silicon pedestal 209, the plunger 255 or the mounted silicon seed.

After installing the upper shaft 235 with the pedestal 209, the upper shaft guide 203 and the shaft 235 are raised so that a path is cleared for loading Silicon pebbles through the upper port 231 into quartz tube 213, while not breaking the seal between base mount 205 and shaft guide 203. This design permits the loading of Silicon pebbles without removal of the upper shaft 235 from the system, while avoiding exposure of the Silicon pebbles to air.

Using a feeding insert, poly-Silicon granules 257 can be loaded through feeding port 231. The slopes of all tubes are selected so that the force of gravity is sufficient to let the Silicon pebbles slide/roll into tube 213.

The loaded Silicon pebbles rest on an inert plunger 255, made of inert material like PTFE, which is clamped into the chuck 214.

The pebbles form a column in quartz tube 213, e.g. 10 cm tall. High purity argon gas purges combined with vacuum cycles—controlled by Ambient Control Unit 507 connected to lower gas port 221 are first used to form an oxygen-free environment. Then the argon gas flow, precisely controlled by control unit 507, is adjusted so that the argon, after passing through a hole pattern in plunger 255, causes the Silicon pebbles to become fluidized, meaning that the pebbles at the top portion of the column become suspended in the flowing argon gas stream. Pebbles at the top of the column carry less weight than those at the bottom and are the first to be lifted up by the gas stream.

In one embodiment, purging efficiency can be enhanced by cycles of high and low pressure. “High pressure” can be generally defined as two atmospheres or higher, and “low pressure” can be generally defined as one milliTorr and lower.

Both shafts 235 and 253, the tube 213, and all support components are attached to carriage frame 223 which can also be raised or lowered. The heater i.e. the RF coil 211 with turns encircling the quartz tube 213 is stationary. Raising and lowering carriage 223 moves the heating zone, which is the area with high radio frequency fields, close to the RF coil 211.

The process steps performed by this equipment are executed by coordinated movements of the shafts and the carriage, and by control of the RF power and the argon flow.

To render Silicon pedestal 209 sufficiently conductive for coupling into the RF field of the RF coil 211, pedestal 209 is positioned adjacent to RF coil 211 such that the bottom section of pedestal 209 is heated the most. Pedestal 209 is pre-heated by radiation from the RF heated susceptor 271. Once pedestal 209 is sufficiently hot and conductive and ready for further heating, susceptor 271 is moved sideways and out of the RF field, so that it does not interfere with subsequent process steps.

In one embodiment of the process, high purity argon gas enters through a lower gas port 221 and exits through an upper gas port 231. To prevent overheating of temperature sensitive parts, the base mount 205 has cooling ports 229 and internal cavities and passages for gas cooling of the base mount and of the end section of the quartz tube 213.

Both shafts 235 and 253 can be cooled by recirculating water and can rotate to equalize temperature non-uniformities, a common practice in the field of crystal growth. FIG. 2 identifies the cooling water seal 201 for the upper shaft 235. Water cooling of the lower shaft 253 is presently considered not necessary for a process involving silicon.

The shafts are connected to their motors with bayonet-type quick-disconnects, identified as 237 in FIG. 2. Shaft guides 203 and 219 provide sealing and mechanical guidance during rotational and vertical movements of the shafts.

During removal of the shafts from the micro-puller for routine cleaning etc. shaft guide and shaft do not have to be taken apart. Handling of the shafts and the shaft guides as one unit provides for easier and more precise assembly and disassembly.

Base mounts, shafts and shaft guides are interchangeable and can be used in the upper or equally the lower location.

In one embodiment, all metal surfaces that could come in contact with material in process are Teflon® coated, eliminating metal contamination.

In one embodiment, the controller system uses an Opto-22® Control System.

FIGS. 3A and 3B illustrate a cross-section of paths which extend capabilities of this described system over previous designs. In FIG. 3A, the silicon pedestal 209 is clamped into the upper shaft 235, which can rotate and perform vertical movements, while keeping the contents of the quartz tube 213 isolated from a contaminating outside environment. The shaft guides 203 and 219 can be raised sufficiently to provide a clear path for loading spherical silicon pebbles 257 into the quartz tube 213 without requiring removal of the shaft 235.

FIG. 3B illustrates an upper clamp 233 which compresses the O-ring between the shaft guide 203 and the base mount 205, securing a tight seal.

FIGS. 4A and 4B show detailed views of both engaged and disengaged positions of the metal susceptor 271. In the engaged position, the susceptor is heated by the RF-field and then acts as radiative heat source for the silicon inside the quartz tube.

FIG. 4B shows a top view with the susceptor 271 in the two positions.

Once the susceptor has accomplished the pre-heating, as evidenced by a beginning glow of the silicon, the susceptor swings into the disengaged position (FIGS. 4A and 4B), and the RF power is raised until the bottom section of the pedestal 209 turns liquid. Next the lower shaft 253 is raised and the argon gas flow adjusted so that the fluidized part of the Silicon-pebble column is moved into the proximity of the liquid part of the pedestal and dancing hot Silicon pebbles come in contact with the melt and go into solution. An upward motion of carriage 223 is then initiated, causing the liquid zone to move downwards. Gradually, more Silicon pebbles go into solution while simultaneously the top section of the melt leaves the hot zone, solidifies, and thereby forms the consolidated poly silicon extension to the silicon pedestal 209. Generally, employment of the susceptor 271 allows for an elimination of an open gas flame process, a significant safety improvement over prior art technology.

FIG. 5 presents a schematic of the Power Distribution, the Environmental Control, and of the physical layout of the total system, arranged in drawers. Beginning with the bottom drawer, the RF-power supply 501 is followed by the RF-generator 503, followed by System Power Supplies 505, followed by Ambient Controls (gas, fluid, vacuum) 507, followed by actuator drives and power supplies 509, followed by controller I/O boards 511, and the CPU 515. Also shown is the automated RF-matching network 215, and sections of the RF-power cable 513, which connects the RF-generator 503 with the matching network 215. The water cooled RF power connection 227 clamps directly into ports in the Tuning Network 215 and feeds RF energy to the water cooled RF coil 211.

FIG. 6 displays a preferred configuration for an ambient control system, which includes the Ambient Control unit 507, which contains components to control the gas flow rate and pressure in the quartz tube 213, plus the gas manifold (not illustrated) with on/off gas controls, which can include a gas pressure regulator and mass flow controller. The ambient control unit 507 also regulates cooling water flow and compressed air flow.

Cooling water is re-circulated from a cooling water supply (not illustrated) through the RF power supply 501, the RF generator 503, the automated tuning RF network 215, the RF coil, and the shafts 235 and 253, if so desired.

The control unit 507 receives argon through line 609 and emits argon to exhaust through line 607. The quartz tube 213 is connected to drawer 507 via lines 615 and 617.

The following part of the disclosure will be generally related to process.

Automated change between various positions of shaft guide 203 and 219 is achieved by a motor, such as a servo motor or a pneumatic motor. During the process, the shaft guide 203 is in the lowest position. All seals are in compressed state, ensuring a leak- and contamination-free environment. Pneumatic linear motors were selected for this function.

The next process step is for the polycrystalline extension to the silicon pedestal 209 to become converted to single crystal silicon.

The lower shaft 253 with shaft guide 219 and plunger 255 and the remaining, unconsumed, Silicon pebbles are taken out. Alternatively, the remaining, unconsolidated Silicon pebbles can also be removed through lower gas port 221. Using an unloading insert in port 221, the gravity driven round Silicon pebbles can be made to glide into a collection vessel.

Next a monocrystalline Silicon seed crystal of proper orientation is mounted on the chuck 214. The whole seed/chuck/shaft/shaft guide assembly is then re-installed into lower base mount 217.

The Silicon source material for the process of single silicon crystal conversion may also originate from silicon manufacturing processes that do not produce granules, but large bodies of polysilicon, such as the Siemens® process. For this machine the only requirement for a conversion from poly- to single-crystal material is that the sample meets the geometrical specification. This can involve the use of roaching tools.

After argon purge cycles, the seed, mounted on chuck 215, and the poly-silicon source mounted on chuck 207 is moved into position for preheating by the RF-heated susceptor 271. After coupling of the poly-crystalline source material to the RF field is achieved, susceptor 271 is moved to the disengaged position and the RF power is raised to melt the bottom of the Silicon polysource material.

The RF power, and the positions of both upper shaft 235 and lower shaft 253 with respect to the RF coil 211, are then selected so that the melted tip of silicon poly-silicon source is in the center of the RF coil 211, and is a few millimeters in length. When too thick, the melt will form a drop that causes damage when it disengages and falls down onto other components.

To begin the single crystal growth process, the lower shaft 253 is raised until the tip of single seed touches the hanging melt of the polysilicon source. The growth rate and the geometry of a growing single crystal are controlled by movements of the carriage 223 and of the shafts 235, 253.

Following techniques common for single crystal growth, a slight melt back of the seed is performed, and, after the establishment of thermal equilibrium, a neck is grown, followed by letting the crystal grow to the desired diameter, before body growth is initiated.

Precise control of all parameters i.e. the thermal environment and various movements, are critical for successful single crystal growth. Besides having tight control of the RF power generator 503 and automated matching network 215, this described system features rotating shafts, thus improving the uniformity of the thermal environment and providing means to influence the convection pattern in the liquid silicon.

After growing the desired crystal length, the growing crystal is separated from the melt, and the system is cooled down. The crystal is harvested and several 2 to 4 mm thick slices are sawn off in specified locations for submission to precision tests, such as Fourier Transform Infra-Red (“FTIR”). Misleading test results may be obtained when the test sample includes material from the Silicon pedestal or when too much seed material entered into the melt.

In the present application, to maintain the relationship between the impurity concentration of the starting granular silicon and the final test sample, purification by the system and by the process is normally undesirable. However, independent control of shaft movements (vertical and rotational) gives the operator a capability to minimize deleterious contributions, such as the addition of Silicon seed material to the material under test.

Finally, a test sample is cut and prepared from the grown single crystal silicon, and submitted to tests, such as FTIR.

In one embodiment, the process steps of consolidation and single-crystal growth, taking advantage of aspects of the system, can be summarized as a series of steps, as follows:

Consolidate Silicon Pebbles:
1. Feed in Silicon pebbles.
2. Seal the system.
3. Argon purge the system with pressure/vacuum cycles.
4. Move shafts and carriage into position.
5. Position susceptor.
6. Do preheat.
7. Swing away susceptor.
8. Set Silicon pedestal position and shaft movements.
9. Form liquid pedestal bottom (set RF-power).
10. Set argon flow to fluidize pebbles.
11. Run process using selected carriage and shaft movements.
12. Shut off process.
13. Remove bottom shaft assembly with plunger and remaining pebbles.

The process using the system continues with the Single Crystal Growth phase.
14. Mount shaft guide/shaft/seed assembly, and seal system.
15. Argon-purge the system with pressure, which can include vacuum cycles;
16. Move shafts and carriage into position.
17. Select shaft movements.
18. Position susceptor.
19. Preheat bottom of poly-Silicon rod which was formed previously, using the RF-heated susceptor.
20. Swing away susceptor.
21. Melt bottom of poly-Silicon using the RF energy from the coil.
22. Do seed-dip by moving seed up.
23. Grow the single crystal making use of the adjustable parameters such as carriage movement, shaft movements, and temperature and gas controls.
24. Separate the single crystal from melt.
25. Unload the single crystal, prepare a test sample for e.g. Optical Tests. Considerations of Cycle Time.

The steps requiring the longest period of time are the consolidation and single crystal growth because of the required achievement of thermal equilibrium and considerations of heat flow and heat of fusion. The time for the many short steps depend on the operator skill, and on the timely availability of prepared components.

Some additional discussion of important construction and engineering details of the system.

For use in a clean room environment, the system can be installed in such a manner, that only the parts directly associated with the quartz tube are on the clean side of a clean room wall. The areas of clean room wall penetrations are minimized.

Microwave power is supplied by a water cooled coil which surrounds the quartz tube, driven by a nominally 10 kW, 3 MHz solid state power source through a water cooled automated matching network. Automatically minimizing the reflected microwave power compensates for impedance changes due to silicon conductivity and melt size changes, and to changes of the load location with regard to the stationary RF-coil.

Safety improvements during the process of pre-heating of Silicon.

To raise the Silicon conductivity enough to achieve coupling to the RF-field, a horseshoe shaped metallic structure, called susceptor 271, is swung in, almost touching the quartz tube 213 and in very close proximity of the RF-coil 211. Radiation from this glowing metal is absorbed by the Silicon and the Silicon temperature rises. Once RF-coupling sets in, a positive feedback cycle takes over: rising temperature causes increased conductivity with increased RF-absorption and so on. The temperature rises very fast. An automated mechanism then removes the susceptor 271. Then the location of the Silicon is optimized for the next process step and the RF-power is adjusted to obtain the desired size of the molten silicon. The elimination of the use of an open flame for silicon pre-heating is considered to be a substantial safety improvement.

The basic principles of the system employ modern drive and control components. All motions of the carriage and the two shafts (vertical and rotational) are achieved by stepping motors or servo motors. The shafts are designed for water cooling. The chassis design stresses mechanical stability, resistance to vibrations, ease of access, maintenance and transportation. The stack of heavy drawers with power sources and control components rests on its own inner frame. The inner frame is rolled into the outer frame and the frames connect at floor level, providing a low center of gravity.

The outer frame, which holds all process related components, has provisions for bolting to the floor.

In one embodiment, the micro-puller system is controlled from a touchscreen, which is linked to the process computer. Parameters like RF-power, gas flow rate, gas valve status, rotations and movements of the shafts, the movement of the carriage, are controlled, monitored and can be adjusted any time. The whole process profile, including the adjustments, is temporarily stored in the computer. It can be permanently saved under a different name, and it is then available for future use and study. Program modifications and process monitoring and control can also be made via Internet.

The system offers water cooled shafts and shaft rotation. Shaft rotations provide for improved temperature uniformity and thereby better dimensional control of the growing crystal. The system offers the possibly to withdraw the shafts far enough out, without exposing the process volume to air, to present a clear path for pebble loading without removal of the upper shaft.

Operator Safety Considerations

Generally, a quartz tube is the mechanically weak spot of the system. Micro cracks, possibly caused during the tube handling and installation, can cause failure under raised or lowered pressure. Operators need to be required to wear eye protection around the machine. Performance of pressure and leak rate tests should be considered after installation of a quartz tube.

The disclosed system and methods can be applied to work with a variety of other materials which require high temperature processing and/or crystal formation. Besides silicon these materials may include Ge, Group III-V Semiconductors as well as some organic crystal materials.

The system may be used for sample preparation from materials prepared by other techniques, such as crystal growth processes of Cz, LEC, and Bridgman, casting processes e.g. for ingots for solar cells, and for source material produced for thin film applications, such as vapor phase, liquid phase epitaxy, or evaporation, sputtering and plasma deposition, MBE and MOCVD processes, etc.

In one embodiment, a micro-puller is used for the conversion of poly-crystalline Silicon pebbles into a single crystal silicon sample as needed for optical characterization.

The micro-puller enables the transformation of poly-Silicon pebbles, as produced by fluid bed processes, into a piece of single crystal silicon of desired crystal orientation, without adding any contamination. A piece of this single crystal Silicon can then be tested by FTIR, as a characterization of the starting material, the poly-Si pebbles. The process takes place in a quartz tube in high purity argon gas.

This conversion process has been accepted industry-wide and published e.g. as ASTM document F 1708-96, “Standard Practice for Evaluation of Granular Polysilicon by Melter-Zoner Spectroscopies,” contained e.g. in the 1998 Annual Book of ASTM Standards, Volume 10.05 Electronics (II). Since 2003 this has not been an active ASTM document anymore, which does not imply that the process is obsolete.

The micro-puller can also be used to prepare a single crystal Silicon sample from a poly crystalline rod, a process described in ASTM F 1723-96.

The micro-puller may be, for example, a GIGA MP 100 Silicon Pebble Converter manufactured by Giga Industries of Garland, Tex.

Growth Environment

To ensure that no contamination is added to the Silicon sample, the Silicon-pebbles do not come in contact with any potential contaminant. They rest on a PTFE plunger in a vertical quartz tube. The metal surfaces which come in contact with the pebbles during loading are coated with Teflon.

The process gas is high purity Argon. The gas flow rate has an upper range high enough to achieve fluidization of the Silicon pebbles.

The gas manifold construction followed rules as appropriate for high vacuum technology, welded steel construction, VCR fittings etc. The gas flow rate is controlled by a mass flow controller and the flow is directed by pneumatic on/off valves. The direction of the gas flow can be reversed, e.g. to support the loading of silicon pebbles from the top without removing the upper shaft. Before the process start, removal of all traces of air is achieved by argon flushing and argon high/low pressure cycles.

For use in a clean room environment, the system can be installed in such a manner, that only the parts directly associated with the quartz tube and the touch screen of the process controller are on the clean side of a clean room wall. The areas of the clean room wall penetrations are minimized.

Power

Microwave power is supplied by a water cooled coil which surrounds the quartz tube, driven by a nominally 10 kW, 3 MHz solid state power source with an automated matching network. This matching network continually minimizes the reflected microwave power, compensating for impedance changes of the coil/silicon system, caused by changes of the load location, the load volume and its conductivity. This improves power control.

Pre-heating of Silicon

To raise the Silicon conductivity enough to achieve coupling to the RF-field, a metal shield is placed in proximity to the RF-coil (also outside the quartz tube) and heated by the RF-energy. Radiation from this hot shield is absorbed by the Silicon, the Silicon temperature is raised and coupling initiated. An automated mechanism then removes the shield.

Mechanical

The basic principles of the system design follow the ASTM F 1708 concept, but employ modern drive and control components. All motions of the carriage and the 2 shafts (vertical and rotational) are achieved by stepping motors. The shafts are water cooled.

The chassis design stresses mechanical stability, ease of access, maintenance and transportation. The power sources and control components rest on a separate rack with drawers, all outside of the clean room.

Controls

The micro-puller is controlled from a touch-screen linked to the process computer. Parameters like RF-power, gas flow rates, gas valve status, rotations and vertical movements of the shafts, the movement of the carriage, are controlled and monitored and can be adjusted any time. The whole process profile, including the adjustments, is temporarily stored in the computer. It can be permanently saved under a different name, and it is then available for future use. Program modifications can also be made via the Internet.

Comments on the Process

The process sequence is detailed in ASTM F 1708, and does not present difficulties to anybody familiar with crystal growth technology and the process requirements for achieving high purity, defect free crystals. For data analysis one has to keep in mind that any crystallization process affects the impurity distribution between the liquid and solid for any contaminant with a segregation coefficient other than 1.

In one embodiment, the micro-puller offers capabilities beyond what is described in ASTM F 1708, such as water cooled shafts and shaft rotation. Shaft rotations provide for improved temperature uniformity and thereby better dimensional control of the growing crystal. However, it has been observed that movements, vertical as well as rotational, of the plunger, which supports a column of Silicon pebbles, leads to grinding actions of the pebbles against the quartz wall and against each other. Therefore it is recommended to use only the carriage movement to present Silicon pebbles to the liquid hanging Silicon tip.

The micro-puller offers the possibly to withdraw the shafts far enough out, without exposing the process volume to air, to present a clear path for pebble loading without removal of the upper shaft.

Operator Safety Considerations

The quartz tube is the mechanically weak spot of the system. Micro cracks, possibly caused during the tube handling and installation, can cause failure under raised or lowered pressure. Operators need to be required to wear eye protection around the machine. Performance of pressure and leak rate tests should be considered after installation of a quartz tube.

Performance of a pressure and leak-rate tests should be considered after the installation of a quartz tube.

The following is a list of controlled components and functions:
Vacuum pump
Vacuum valve
Upper shaft guide
Upper base mount
Upper shaft vertical move
Upper shaft rotation
Pre-heater position
Lower shaft vertical move
Lower shaft rotation
Lower base mount
Lower shaft guide
Carriage vertical move
Mass flow meter
Gas pressure control, which may be manually set
RF power
5 or 6 gas open/closed valves

Dimensions
Quartz tube
Quartz tube length
O-Rings for various functions

Utilities
List of power requirements
Gas volume and pressure
Cooling water (RF generator+shafts)

Size
Height, footprint
System weight

The following components are illustrated in the attached FIGURES:

upper shaft
rotation (stepp/motor)
up/down(linear drive/stepp/motor)

shaft guide
3-position air drive

clamp
air motor

base mount

chuck with pedestal

carriage
up/down (linear drive/stepp/motor)

RF coil

chuck w. plunger or seed crystal

base mount

clamp
air motor

shaft guide
3-position air drive

lower shaft
up/down linear drive/stepp/motor)
rotation (stepp/motor)

The mission of the micro-puller is to standardize the fabrication of test samples through this Float Zoner design to achieve repeatable results by each operator.

The purpose of an Evaluation Float Zoner is to convert the starting granular silicon into single crystal material from which test samples for optical or other tests can be produced, without the introduction of additional impurities.

To maintain the relationship between the impurity concentration of the starting granular silicon and the final test sample, purification by the Evaluation Float Zoner is normally undesirable.

In the Evaluation Float Zoner as used in the application disclosed herein, the produced silicon diameter and length are so small that relative pull speed and necking are not necessary to achieve crystal orientation and single crystal growth as in a crystal puller. Users express a desire for rotation as a stabilizing element for single-crystal growth, and the ability to neck the crystal by adding linear travel at each crystal chuck.

The ASTM document ASTM F 1705-96 describes the process well; it is a 2-step process plus optical tests. To summarize:

A:
1. The Silicon pedestal is mounted from the top in the pedestal chuck.
2. The PTFE-plunger is mounted from the bottom in place of the seed chuck.
3. The pellets are added; argon is turned on to flow through the pellets.
4. The RF-coil heats the Silicon pedestal (after preheat to enable coupling).
5. The pellets are brought in contact with the molten bottom of the pedestal.
6. The plunger and pellets are lifted until the pellets begin to dissolve into the molten lower end of the pedestal.
7. The carriage is moved up growing the crystal down.
8. When done, let it all cool, take the plunger and the remaining pellets out.

B:
1. Mount a Silicon seed on the bottom chuck (where the PTFE plunger was before).
2. Lift the seed crystal until it “touches”“the poly-rod; turn on argon.
3. The RF-coil heats the Silicon pedestal (after preheat to enable coupling).
4. Raise the liquid seed end (with the seed from below) to touch the molten polyrod and begin zone-melting the crystal (carriage moves up with the crystal growing down).
5. When done, let the crystal cool and harvest the crystal.

C:
Cut a test slice; do optical analysis (FTIR)

Cycle Time

Cycle time counts from the time the equipment is ready for loading until it is ready to load the next samples.

The process consists of the following steps:

Consolidate Silicon Pebbles:
1. Feed in Silicon pebbles.
2. Seal the system.
3. Argon purge the system with pressure/vacuum cycles.
4. Move shafts and carriage into position.
5. Position preheater.
6. Do preheating. −5 min
7. Swing away preheater.
8. Set Silicon pedestal position.
9. Form liquid pedestal bottom (set RF-power). −5 min
10. Set argon flow to fluidize pebbles.
11. Run process using selected carriage and shaft movements. −20 min
12. Shut off process and let system cool down. −20 min
13. Remove bottom shaft assembly with plunger and remaining pebbles.

Single Crystal Growth

Assumption: an extra shaft guide with a shaft and a mounted seed crystal is ready
13. Mount shaft guide/shaft/seed assembly, seal system.
14. Argon purge the system with pressure/vac cycles.
15. Move shafts and carriage into position.
16. Select shaft rotations.
17. Positions preheater.
18. Preheat bottom of poly-Silicon rod. −5 min
19. Swing away preheater.
20. Melt bottom of poly-Silicon rod. −5 min
21. Do seed-dip by moving seed up. −5 min
22. Do single crystal growth estimate. −30 min (seed/melt position/temperature sequence)
23. Separate single crystal from melt.
24. Let system cool down. −20 min
25. Remove single crystal with shaft/shaft guide.

The steps requiring the longest period of time are the consolidation (step 11), single crystal growth (step 22) and the cool down periods (steps 10, 24). The time for the many short steps depend on the operator skill, and on the timely availability of prepared components. A complete cycle could be completed in about 3 hours. A cycle for the replacement/cleaning of the quartz tube has to be established experimentally. A cycle for major cleaning of components like shafts, plungers etc. will have to be established.

Those skilled in the art to which this application relates will appreciate that other and further additions, deletions, substitutions and modifications may be made to the described embodiments.

1-20. (canceled)

21. A Silicon pebble converter, comprising:
a quartz process tube;
a plunger located within a lower section of the quartz process tube for supporting Silicon pebbles;
a Silicon pedestal located within an upper section of the quartz tube above the Silicon pebbles;
a radio-frequency (RF) coil encircling the quartz process tube, the RF coil configured to heat the Silicon pebbles within the quartz process tube; and
a moveable RF-heated susceptor configured to pre-heat the Silicon pedestal, the RF-heated susceptor partially surrounding the quartz tube in a first position adjacent to the RF coil, the RF-heated susceptor heated by radiation from the RF coil in the first position, the RF-heated susceptor configured to move to second position at a distance away from the quartz process tube and the RF coil when the pedestal has been pre-heated to a desired temperature.

22. The Silicon pebble converter of claim 1, further comprising:
an upper mount coupling the Silicon pedestal to an upper shaft that permits vertical and rotational movement of Silicon pedestal; and
a lower mount coupling the plunger to a lower shaft that permits vertical and rotational movement of the plunger.

23. The Silicon pebble converter of claim 22, further comprising:
a control system configured to drive the upper shaft to control movement of the Silicon pedestal within the quartz process tube, the control system configured to drive the lower shaft to control movement of the plunger within the quartz process tube.

24. The Silicon pebble converter of claim 23, further comprising:
a carriage coupled to the quartz process tube, the control system configured to control movement of the carriage to adjust positioning of the quartz process tube relative to the RF coil.

25. The Silicon pebble converter of claim 23, wherein the control system is configured to follow a pre-programmed process sequence for consolidation of the Silicon pebbles into a polysilicon rod and for conversion of the polysilicon rod into a monocrystaline test sample.

26. The Silicon pebble converter of claim 25, wherein the control system is coupled to the Internet and is configured to receive the pre-programmed process sequence from a remote location.

27. The Silicon pebble converter of claim 21 mounted on a preloaded support frame configured to position process components within a clean room and to position user and support components in a non-clean room.

28. The Silicon pebble converter of claim 21, further comprising a polytetrafluoroethylene based hybrid coating on the components within the inert environment.

29. A method for converting Silicon pebbles into a crystal Silicon sample, comprising:
feeding Silicon pebbles onto a pedestal in a quartz process tube;
positioning a Silicon pedestal in the quartz process tube above the Silicon pebbles so that a bottom of the Silicon pedestal is adjacent to a radio-frequency (RF) coil;
positioning an RF-heated susceptor above the RF coil and partially surrounding the quartz tube in a first position adjacent to the Silicon pedestal;
pre-heating the Silicon pedestal using the RF coil and the RF-heated susceptor heated by radiation from the RF coil; and
when the Silicon pedestal is heated to a desired temperature, moving the RF-heated susceptor to second position at a distance away from the quartz process tube and the RF coil.

30. The method of claim 29, further comprising:
alternating argon gas purges and vacuum cycles within the quartz tube to create an oxygen-free and chemically inert environment.

31. The method of claim 30, further comprising:
after the argon gas purges and vacuum cycles, adjusting an argon gas flow so that the argon gas causes the Silicon pebbles to become fluidized, wherein Silicon pebbles at a top portion of a Silicon pebble column are suspended in a flowing argon gas stream.

32. The method of claim 29, further comprising:
raising the plunger until the fluidized bed of silicon pebbles begins to transfer to the hanging melt on the silicon pedestal, growing the poly crystal, the melt caused by radiation from the RF coil.

33. The method of claim 32, further comprising:
controlling movement of the plunger, quartz process tube, argon gas flow, and Silicon plunger using a control system.

34. The method of claim 33, further comprising:
managing a growth rate and geometry of a growing crystal within the quartz process tube by the control system driving movements of the plunger, quartz process tube, and Silicon plunger.

35. The method of claim 33, wherein the control system is configured to follow a pre-programmed process sequence for consolidation of the Silicon pebbles into a polysilicon rod and for conversion of the polysilicon rod into a monocrystaline test sample.

36. The method of claim 35, wherein the control system is coupled to the Internet and is configured to receive the pre-programmed process sequence from a remote location.

37. The method of claim 35, further comprising:
repeating growth of a Silicon crystal using a stored pre-programmed process sequence.

38. A system for converting poly-Silicon material into a single crystal material, comprising:
a seed chuck located within a lower section of a quartz process tube, configured to support single crystal silicon seeds;
a lower mount coupling the seed chuck to a lower shaft that permits vertical and rotational movement of the seed chuck;
a Silicon pedestal located within an upper section of the quartz tube above the Silicon pebbles;
an upper mount coupling the Silicon pedestal to an upper shaft that permits vertical and rotational movement of Silicon pedestal;
a radio-frequency (RF) coil encircling the quartz process tube, the RF coil configured to heat the Silicon pebbles within the quartz process tube;
a carriage coupled to the quartz process tube; and
a moveable RF-heated susceptor configured to pre-heat the Silicon pedestal, the RF-heated susceptor partially surrounding the quartz tube in a first position adjacent to the RF coil, the RF-heated susceptor heated by radiation from the RF coil in the first position, the RF-heated susceptor configured to move to second position at a distance away from the quartz process tube and the RF coil when the pedestal has been pre-heated to a desired temperature.

39. The system of claim 38, further comprising:
a control system configured to control movement of the Silicon pedestal within the quartz process tube, to control movement of the seed chuck within the quartz process tube, and to control movement of the carriage to adjust positioning of the quartz process tube relative to the RF coil

40. The system of claim 39, wherein the control system is configured to follow a pre-programmed process sequence for consolidation of the Silicon pebbles into a polysilicon rod and for conversion of the polysilicon rod into a monocrystaline test sample, and wherein the control system is coupled to the Internet and is configured to receive the pre-programmed process sequence from a remote location.
